(19) United States
(12) Patent Application Publication
(10) Pub. No.: US 2003/0108821 A1
(43) Pub. Date: Jun. 12, 2003

(54) Microlens array fabrication

(76) Inventors: Wenhui Mei, Plano, TX (US); Kin Foong Chan, Plano, TX (US); Ren Yang, Richardson, TX (US)

Correspondence Address: HAYNES AND BOONE, LLP, 901 MAIN STREET, SUITE 3100, DALLAS, TX, 75202, US

(21) Appl. No.: 09/683,271

(22) Filed: Dec. 6, 2001

(51) Int. Cl. G03F 7/00

(52) U.S. Cl. 430/321

(57) ABSTRACT

A new and unique method for fabricating a microlens array is provided. First, a mask layer is applied to an optical substrate. One or more holes are then created in the mask layer so that corresponding first cavities can then be created in the substrate. Each of these first cavities has a predetermined depth and a first width. The mask layer is then removed so that one or more second cavities can be created in the substrate, the second cavities corresponding with the first cavities. Each of these second cavities has approximately the same predetermined depth as the corresponding first cavity and having a second width greater than the first width.

### BACKGROUND

The present invention relates generally to optical devices, and more particularly to a method for fabricating a microlens array.

Microlens arrays are key elements in optical interconnection and processing systems. There are many different types of microlens arrays, including arrays of one or more very small refractive or diffractive lens. Microlens arrays are conventionally fabricated by directly applying a laser beam onto a photoresist-coated substrate. After chemical development of the photoresist, a continuous-relief microlens arrays can be etched in glass or infra-red (IR) transmissive materials, or used to produce replicas by casting, embossing, or injection molding technologies.

It is desired to improve on the conventional fabrication methods for making microlens arrays.

### SUMMARY

A technical advance is provided by a new and unique method for fabricating a microlens array. In one embodiment, a mask layer is applied to a substrate. One or more holes are then created in the mask layer so that corresponding first cavities in the substrate can then be created. Each of these first cavities has a predetermined depth and a first width. The mask layer is then removed so that one or more second cavities can be created in the substrate, the second cavities corresponding with the first cavities. Each of these second cavities has approximately the same predetermined depth as the corresponding first cavity and having a second width greater than the first width.

In some embodiments, the substrate is made of an optical material and the microlens array comprises one or more negative lens elements corresponding to the one or more second cavities.

In some embodiments, the substrate with the one or more second cavities is used as a mold to create the microlens array. In this way, the microlens array comprises one or more positive lens elements corresponding to the one or more second cavities.

In some embodiments, a resist coating is applied on top of the mask layer. The resist coating can then be exposed with an image, the image including one or more hole shaped patterns corresponding to the one or more holes in the mask layer. The step of creating the one or more holes in the mask layer can then utilize a third etching process and the exposed resist coating.

In some embodiments, the one or more holes are spaced at a distance equal to the second width, such as about 10 microns.

### BRIEF DESCRIPTION OF DRAWINGS

FIG. 1 is a front view of a microlens array of positive lens elements.

FIG. 2 is a side view of the microlens array of FIG. 1.

FIGS. 3 6 are side views of a substrate during various steps of a processing operation according to various embodiments of the present invention.

FIG. 7. is a side view of a microlens array of negative lens elements. Alternatively, FIG. 7 is a side view of a mold for making the microlens array of positive lens elements of FIGS. 1-2.

### DETAILED DESCRIPTION

The present disclosure relates to fabricating microlens arrays, such as can be used in a wide variety of applications. It is understood that the following disclosure provides many different embodiments, or examples, for implementing different features of the invention in specific applications. These embodiments are, of course, merely examples and are not intended to limit the invention from that described in the claims.

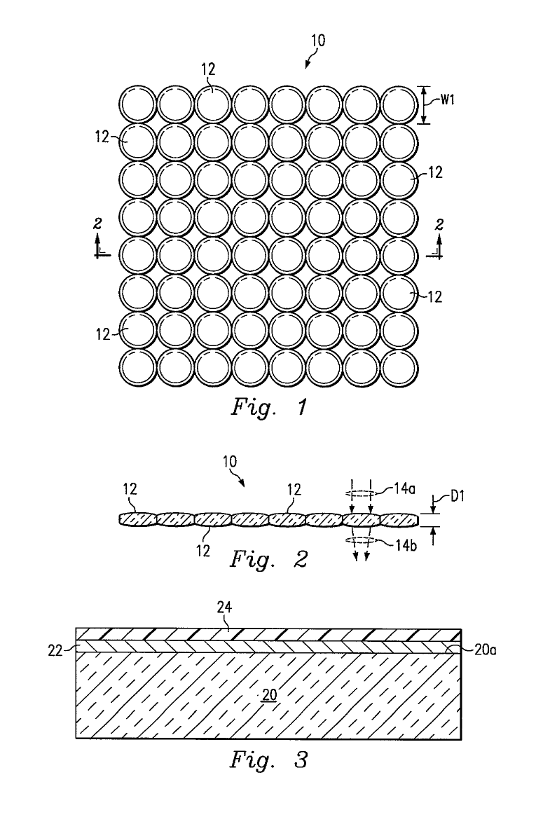

Referring now to FIGS. 1 and 2, the reference numeral 10 designates, in general, one embodiment of a microlens array. In the present embodiment, the microlens array 10 is an 8×8 array of circular positive lens elements 12, with each lens element 12 having a diameter W1 of about 10 microns and a maximum thickness D1 of about 5 microns. Although it appears from the figures that the individual lens elements 12 are adjacent to each other, it is understood that some embodiments may utilize a predetermined spacing between the lenses.

In the present embodiment, each of the lens elements 12 is convex in shape, it being understood that various shapes can be used, depending on the application of use for the microlens array 10. Each convex lens elements 12 is operable to direct an incoming light 14a towards a focal point, as illustrated by outgoing light 14b. In this way, the microlens array 10 can individually focus 64 (8×8) different projections of light onto 64 different focal points. It is understood, however, that other embodiments may have many more lens elements 12 and each lens may not be of a shape as other lenses in the array 10.

The microlens array 10 is similar to many conventional microlens arrays, except that it is created by a new and unique fabrication process, discussed in greater detail below. The microlens array 10 is improved over most conventional microlens arrays, however, because of the increased level of control provided by the following fabrication process.

Referring now to FIG. 3, to begin with, a substrate 20 is provided for manufacturing the microlens array. For the sake of example, the substrate 20 is a flat, wafer-shaped substrate of optical-grade material, such as quartz. On a top surface 20a of the substrate 20 is placed a metal film mask material 22 and on top of that, a resist coating 24. It is understood that the construction and application of the substrate 20, metal film 22, and the resist coating 24 are well known in the art.

In another embodiment, no mask material 22 is required. In this embodiment, the resist coating 24 can perform the function of the mask material 22, as discussed in further detail, below.

Referring now to FIG. 4, one or more apertures 30 are formed in the mask material 22. There is one aperture for each microlens of the eventual microlens array (e.g., FIG. 1) that is being fabricated. The apertures 30 are relatively small, such as 2 5 microns in diameter. The apertures are created, for example, by exposing an appropriate image of aperture patterns onto the resist coating 24 and then removing the corresponding resist coating and metal film. It is understood that other processing techniques can be used to create the apertures 30.

Referring now to FIG. 5, the resist coating 24 is then removed and a first etching process is applied to the substrate 20 through the apertures 30. The etching process may be one of many different types of processes, such as one that uses a wet etchant 32. The wet etchant 32 reacts with all the surfaces of the substrate 20 in which it contacts. This includes the portion of the substrate 20 accessible through the apertures 30, but does not include the portions of the substrate that are protected by the mask material 22.

The etchant 32 is allowed sufficient time to react with portions of the substrate 20, one for each aperture 30, until cavities 40 are formed corresponding to each aperture. As shown in FIG. 5, the cavities 40 are formed when the etchant 32 reacts in the directions indicated by arrows e2, e3, and e4, such that: e2=e3=e4.

It is further noted that no etching occurs under the mask material 22, such that: e1=0.

The etching process is allowed to continue until each cavity 40 is of a predetermined well depth D2 and a well width W2, for example 5 microns each. The well depth D2 will remain relatively constant in the subsequent processing operations, as will be discussed in greater detail below. The etchant 32 (including the etched material that previously created the cavity 40) is then removed by a cleaning process, such as one that uses de-ionized water.

Referring now to FIG. 6, once the depth D2 has been achieved, the mask material 22 is removed using conventional techniques. Once the mask material 22 is removed, a second etching process is applied to the substrate 20. The etching process may be similar to the first etching process, such as one that uses a wet etchant 42. The etchant 42 is allowed sufficient time to remove (after cleaning) portions of the substrate 20, one for each cavity 40. As shown in FIG. 6, the cavities 40 expand when the etchant 42 reacts in the directions indicated by arrows e11, e12, e13, and e14, such that: e11=e12=e13=e14.

As contrasted with the prior etching process illustrated in FIG. 5, during the second etching process, the etching that occurs in the direction e11 is equal to and in the same direction as the etching that occurs in the direction e13. As a result, the well depth D2 does not change during the second etching process. However, the well width does change to a new value W3 because of the etching that occurs in the directions e12 and e14.

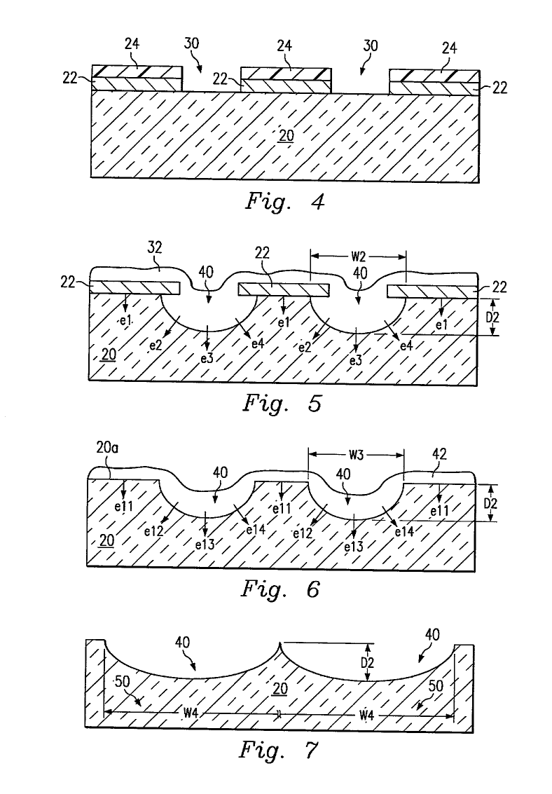

Referring to FIG. 7, the second etching process illustrated in FIG. 6 will eventually expand the cavities 40 to a well width W4 while maintaining the previously determined well depth D2. The well width W4 can be chosen to produce a size for lens elements (determined by the cavities 40) that achieve a desired level of integration and connectivity between elements. Once complete, the second etchant 42 (FIG. 6) is removed by conventional processes such as cleaning.

This process forms a negative microlens array of negative lens elements 50, determined by the cavities 40 and the substrate 20. These negative lens elements 50 may be used as is, or may be used as a mold to form an array of positive elements, such as those illustrated in FIGS. 1-2.

While the invention has been particularly shown and described with reference to the preferred embodiment thereof, it will be understood by those skilled in the art that various changes in form and detail may be made therein without departing form the spirit and scope of the invention.

What is claimed is:

1. A method of manufacturing a microlens array, the method comprising the steps of:
applying a mask layer to a substrate;
creating one or more holes in the mask layer;
performing a first etching process on the substrate with the mask layer applied to the substrate, the first etching process creating one or more first cavities corresponding to the one or more holes in the mask layer, each first cavity having a predetermined depth and a first width;
removing the mask layer;
performing a second etching process on the substrate with the mask layer removed from the substrate, the second etching process creating one or more second cavities corresponding to the one or more first cavities, each second cavity having the same predetermined depth as the corresponding first cavity and having a second width greater than the first width.

2. The method of claim 1 wherein the substrate is made of an optical material and the microlens array created by the method comprises one or more negative lens elements corresponding to the one or more second cavities.

3. The method of claim 1 further comprising the step of:
using the substrate with the one or more second cavities as a mold to create the microlens array;
wherein the microlens array comprises one or more positive lens elements corresponding to the one or more second cavities.

4. The method of claim 1 further comprising the step of:
applying a resist coating on top of the mask layer;
exposing an image onto the resist coating, the image including one or more hole shaped patterns corresponding to the one or more holes in the mask layer; and
wherein the step of creating the one or more holes in the mask layer utilizes a third etching process and the exposed resist coating.

5. The method of claim 1 wherein the one or more holes are spaced at a distance equal to the second width.

6. The method of claim 5 wherein the distance is 10 microns.

7. A method of manufacturing a microlens array from a single monolithic substrate, the method comprising the steps of:
applying a metal layer to a surface of the substrate;
applying a resist layer onto the metal layer, the resist layer being opposite from the substrate;
exposing a pattern onto the resist layer, the pattern including a two-dimensional array of circles;
performing a first etching process on the exposed resist layer to create a two-dimensional array of holes in the metal layer, wherein the first etching process does not react with the substrate;
performing a second etching process on the substrate with the mask layer applied to the substrate, wherein the second etching process does not react with the metal layer but does react with the substrate, the second etching process creating a two-dimensional array of first cavities corresponding to the two-dimensional array of holes in the mask layer, each first cavity having a predetermined depth and a first width;
removing the metal layer;
performing a third etching process on the substrate with the metal layer removed from the substrate, the third etching process creating a two-dimensional array of second cavities, the second cavities being enlarged versions of corresponding first cavities, each second cavity having the same predetermined depth as the corresponding first cavity and having a second width greater than the first width.

8. The method of claim 7 wherein the substrate is made of an optical material and the microlens array created by the method comprises a two-dimensional array of negative lens elements corresponding to the two-dimensional array of second cavities.

9. The method of claim 7 further comprising the step of:
using the substrate with the two-dimensional array of second cavities as a mold to create the microlens array;
wherein the microlens array comprises a two-dimensional array of positive lens elements corresponding to the two-dimensional array of second cavities.

10. The method of claim 1 wherein the two-dimensional array of holes are spaced at a distance equal to the second width.

11. The method of claim 10 wherein the distance is 10 microns.
